(19) United States
(12) Patent Application Publication
(10) Pub. No.: US 2026/0020220 A1
(43) Pub. Date: Jan. 15, 2026

(54) SEMICONDUCTOR MEMORY DEVICE AND MANUFACTURING METHOD THEREOF

(71) Applicant: Samsung Electronics Co., Ltd., Suwon-si (KR)

(72) Inventors: Sunghwan Jang, Suwon-si (KR); Hyojin Park, Suwon-si (KR)

(21) Appl. No.: 19/013,527

(22) Filed: Jan. 8, 2025

(30) Foreign Application Priority Data
Jul. 11, 2024 (KR) 10-2024-0092012

(51) Int. Cl. H10B 12/00

(52) U.S. Cl. CPC H10B 12/30; H10B 12/03; H10B 12/05

(57) ABSTRACT

A semiconductor memory device according to embodiments includes a semiconductor pattern, a gate electrode extending in a first direction on the semiconductor pattern, a data storage element electrically connected to the semiconductor pattern, and a spacer adjacent to the gate electrode in a second direction crossing the first direction. The semiconductor pattern includes a first impurity region adjacent to the bit line, a second impurity region adjacent to the data storage element, and a channel region between the first impurity region and the second impurity region. The data storage element includes a first electrode electrically connected to the second impurity region. An outer sidewall of the spacer, which is opposite the gate electrode, is closer to the gate electrode than an outer sidewall of the first electrode, which is opposite the second impurity region.

### CROSS-REFERENCE TO RELATED APPLICATION

This application is based on and claims priority under 35 U.S.C. § 119 to Korean Patent Application No. 10-2024-0092012, filed on Jul. 11, 2024, in the Korean Intellectual Property Office, the disclosure of which is incorporated by reference herein in its entirety.

### TECHNICAL FIELD

The inventive concept relates to a semiconductor memory device and a method of manufacturing the same, and more specifically, to a three-dimensional semiconductor memory device with improved electrical characteristics and a method of manufacturing the same.

### BACKGROUND

In order to meet consumer demand for high performance and low price, an increase in the integration of semiconductor memory devices may be required. In the case of semiconductor memory devices, the degree of integration thereof may be a factor in determining the price of the product, so increased integration may be particularly desirable. In the case of two-dimensional or planar semiconductor memory devices, integration may be primarily determined by the area occupied by a unit memory cell, and may be affected by the level of fine pattern formation technology. However, because expensive equipment may be required for pattern miniaturization, there may be limitations on integration of two-dimensional semiconductor memory devices. Accordingly, three-dimensional semiconductor memory devices having memory cells arranged three-dimensionally have been proposed.

### SUMMARY

The inventive concept provides a three-dimensional semiconductor memory device with improved electrical characteristics and reliability.

The inventive concept provides a method of manufacturing a three-dimensional semiconductor memory device with improved electrical characteristics and reliability.

The problems to be solved by the present inventive concept are not limited to the problems mentioned above, and other problems not mentioned will be clearly understood by those skilled in the art from the following description.

According to an aspect of the inventive concept, there is provided a semiconductor memory device including a stack structure comprising a plurality of layers stacked on a substrate, each of the plurality of layers comprising a semiconductor pattern, a gate electrode extending in a first direction on the semiconductor pattern, and an information storage element electrically connected to the semiconductor pattern; a bit line on one side of the stack structure and extending in a direction perpendicular to the substrate; and a spacer adjacent to the gate electrode in a second direction intersecting the first direction. The semiconductor pattern comprises a first impurity region adjacent to the bit line, a second impurity region adjacent to the information storage element, and a channel region between the first impurity region and the second impurity region. The information storage element comprises a first electrode electrically connected to the second impurity region. An outer sidewall of the spacer, which is opposite the gate electrode, is closer to the gate electrode than an outer sidewall of the first electrode, which is opposite the second impurity region.

According to an aspect of the inventive concept, there is provided a semiconductor memory device including a stack structure comprising a plurality of layers stacked on a substrate, each of the plurality of layers comprising a semiconductor pattern, a gate electrode extending in a first direction on the semiconductor pattern, and an information storage element electrically connected to the semiconductor pattern; a bit line on one side of the stack structure and extending in a direction perpendicular to the substrate; and a spacer adjacent to the gate electrode in a second direction intersecting the first direction. The semiconductor pattern comprises a first impurity region adjacent to the bit line, a second impurity region adjacent to the information storage element, and a channel region between the first impurity region and the second impurity region. An impurity concentration of the second impurity region increases away from the bit line in the second direction.

According to an aspect of the inventive concept, there is provided a semiconductor memory device including a substrate; an insulating film on the substrate; a semiconductor pattern on the insulating film, the semiconductor pattern comprising a channel region, a first impurity region on a first end of the channel region, and a second impurity region on a second end of the channel region, wherein the second end faces the first end in a first direction; a gate electrode intersecting the semiconductor pattern in a second direction that intersects the first direction; a gate insulating pattern between the channel region and the gate electrode; a spacer adjacent to the gate electrode and the insulating film in the first direction, the spacer overlapping the second impurity region in a direction perpendicular to the substrate; a bit line adjacent to the first impurity region in the first direction, the bit line being electrically connected to the first impurity region; and an information storage element electrically connected to the second impurity region. The information storage element comprises a first electrode directly connected to the second impurity region, a second electrode, and a dielectric film therebetween. An outer sidewall of the first electrode, which is opposite the second impurity region, is farther from the gate electrode in the first direction than an outer sidewall of the spacer, which is opposite the gate electrode.

### BRIEF DESCRIPTION OF THE DRAWINGS

Embodiments will be more clearly understood from the following detailed description taken in conjunction with the accompanying drawings in which:

FIG. 1 is a simplified circuit diagram showing a cell array of a three-dimensional semiconductor memory device according to embodiments;

FIGS. 2, 3, 4, 5, and 6 are perspective views showing three-dimensional semiconductor memory devices according to embodiments, respectively;

FIG. 7 is a cross-sectional view taken along line A-A′ of FIG. 3;

FIG. 8 is an enlarged view of CX1 of FIG. 7;

FIG. 9 is a cross-sectional view taken along line A-A′ of FIG. 3;

FIG. 10 is an enlarged view of CX2 of FIG. 9;

FIGS. 11A, 11B, 11C, 11D, 11E, 11F, and 11G are diagrams showing a method of manufacturing the semiconductor memory device of FIG. 7, and are cross-sectional views taken along line A-A′ of FIG. 3;

FIG. 12 is a cross-sectional view taken along line A-A′ of FIG. 3;

FIG. 13 is a cross-sectional view taken along line A-A′ of FIG. 3; and

FIG. 14 is a cross-sectional view taken along line B-B′ of FIG. 6.

### DETAILED DESCRIPTION OF EMBODIMENTS

Hereinafter, embodiments of the inventive concept will be described in detail with reference to the accompanied drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

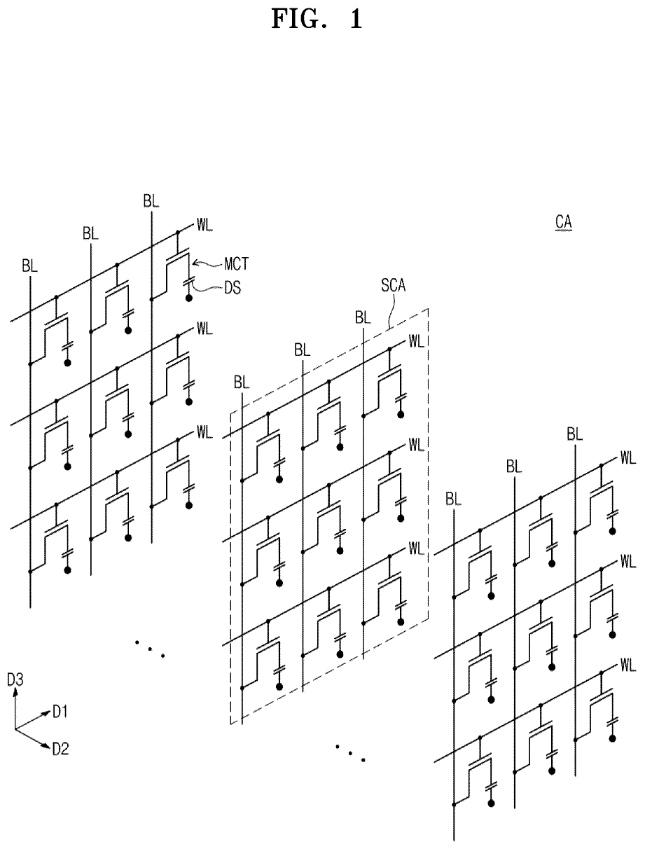

FIG. 1 is a simplified circuit diagram showing a cell array of a three-dimensional semiconductor memory device according to embodiments.

Referring to FIG. 1, a cell array CA of a three-dimensional semiconductor memory device according to embodiments may include a plurality of sub-cell arrays SCAs. The sub-cell arrays SCAs may be arranged in a second horizontal direction D2.

Each of the sub-cell arrays SCAs may include a plurality of bit lines BL, a plurality of word lines WL, and a plurality of memory cell transistors MCT. One memory cell transistor MCT may be arranged between one word line WL and one bit line BL.

The bit lines BL may be conductive patterns (e.g., metal lines) extending in a vertical direction (i.e., a vertical direction D3) from a substrate. The bit lines BL in one sub-cell array SCA may be arranged in a first horizontal direction D1. The adjacent bit lines BL may be spaced apart in the first horizontal direction D1.

The word lines WL may be conductive patterns (e.g., metal lines) that are stacked on the substrate in the vertical direction D3. Each of the word lines WL may extend in the first horizontal direction D1. The adjacent word lines BL may be spaced apart in the vertical direction D3.

A gate of the memory cell transistor MCT may be connected to the word line WL, and a first source/drain of the memory cell transistor MCT may be connected to the bit line BL. The second source/drain of the memory cell transistor MCT may be connected to a data storage element DS. For example, the data storage element DS may be a capacitor. The second source/drain of the memory cell transistor MCT may be connected to the first electrode of the capacitor.

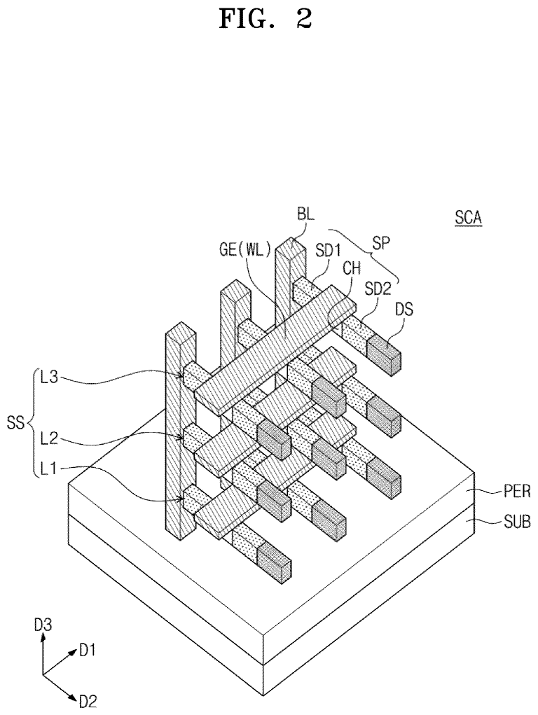

FIGS. 2 to 6 are perspective views illustrating three-dimensional semiconductor memory devices according to embodiments.

First, referring to FIGS. 1 and 2, a peripheral circuit region PER may be provided on a substrate SUB. The substrate SUB may include a silicon substrate, a germanium substrate, or a silicon-germanium substrate. The peripheral circuit region PER may include peripheral transistors provided on the substrate SUB. The peripheral circuit region PER may include a circuit for operating a memory cell array according to embodiments.

One of a plurality of sub-cell arrays SCA described with reference to FIG. 1 may be provided on the peripheral circuit region PER. Specifically, a stack structure SS including first to third layers L1, L2, and L3 may be provided on the peripheral circuit region PER. The first to third layers L1, L2, and L3 of the stack structure SS may be stacked spaced apart from each other in the vertical direction (i.e., the vertical direction D3). Each of the first to third layers L1, L2, and L3 may include a plurality of semiconductor patterns SP, a plurality of information storage elements DS, and a gate electrode GE.

The semiconductor patterns SP may have a line shape or a bar shape extending in the second horizontal direction D2. The semiconductor patterns SP may include a semiconductor material, such as silicon, germanium, or silicon-germanium. For example, the semiconductor patterns SP may include polysilicon or single crystal silicon.

Each of the semiconductor patterns SP may include a channel region CH, a first impurity region SD1, and a second impurity region SD2. The channel region CH may be disposed between the first impurity region SD1 and the second impurity region SD2. The channel region CH may correspond to a channel of the memory cell transistor MCT described with reference to FIG. 1. The first impurity region SD1 and the second impurity region SD2 may correspond to the first source/drain and the second source/drain of the memory cell transistor MCT described with reference to FIG. 1, respectively.

The first impurity region SD1 and the second impurity region SD2 may be regions in which the semiconductor pattern SP is doped with impurities. Therefore, the first impurity region SD1 and the second impurity region SD2 may be of a conductivity type of n-type or p-type. The first impurity region SD1 may be formed adjacent to a first end of the channel region CH, and the second impurity region SD2 may be formed adjacent to a second end of the channel region CH. The second end may face the first end in the second horizontal direction D2.

The information storage elements DS may be respectively connected to the semiconductor patterns SP. Specifically, the information storage elements DS may be respectively connected to the second impurity regions SD2 of the semiconductor patterns SP. The information storage elements DS may be memory elements capable of storing data. Each of the information storage elements DS may include a memory element using a capacitor, a memory element using a magnetic tunnel junction pattern, or a memory element using a variable resistor including a phase change material. For example, each of the information storage elements DS may be a capacitor.

The gate electrodes GE may have a line shape or a bar shape extending in the first horizontal direction D1. The gate electrodes GE may be stacked spaced apart from each other in the vertical direction D3. Each of the gate electrodes GE may extend across the semiconductor patterns SP within one layer in the first horizontal direction D1. In other words, the gate electrodes GE may be horizontal word lines WL described with reference to FIG. 1. The gate electrodes GE may include a conductive material. For example, the conductive material may be one of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.).

A plurality of bit lines BL extending in the vertical direction may be provided on the substrate SUB. Each of the bit lines BL may have a line shape or a pillar shape extending in the vertical direction D3. The bit lines BL may be arranged in the first horizontal direction D1. Each of the bit lines BL may be electrically connected to the first impurity regions SD1 of the vertically stacked semiconductor patterns SP.

The bit lines BL may include a conductive material, and the conductive material may be any one of a doped semiconductor material, a conductive metal nitride, a metal, and a metal-semiconductor compound. The bit lines BL may be the vertical bit lines BL described with reference to FIG. 1.

Among the first to third layers L1, L2, and L3, the first layer L1 is described in detail. The semiconductor patterns SP of the first layer L1 may be arranged in the first horizontal direction D1. The semiconductor patterns SP of the first layer L1 may be at the same level, i.e., a same vertical distance (e.g., in the direction D3) relative to a reference layer or surface (e.g., the substrate SUB). The gate electrode GE of the first layer L1 may extend in the first horizontal direction D1 across the semiconductor patterns SP of the first layer L1. For example, the gate electrode GE of the first layer L1 may be provided on upper surfaces of the semiconductor patterns SP. Spatially relative terms such as ‘above,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures.

Although not shown, a gate insulating film may be disposed between the gate electrode GE and the channel region CH. The gate insulating film may include at least one of a high-k dielectric film, a silicon oxide film, a silicon nitride film, and a silicon oxynitride film. For example, the high-k dielectric film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Each of the bit lines BL may be connected to the first end of the semiconductor pattern SP of the first layer L1. For example, the bit line BL may be directly connected to the first impurity regions SD1. In another example, the bit line BL may be electrically connected to the first impurity region SD1 through a metal silicide. The descriptions of the second layer L2 and the third layer L3 may be substantially the same as the first layer L1 described above.

Although not shown, empty spaces within the stack structure SS may be filled with an insulating material. For example, the insulating material may include at least one of a silicon oxide film, a silicon nitride film, and a silicon oxynitride film. A wiring layer electrically connected to the sub-cell array SCA may be provided on the stack structure SS. The wiring layer may be electrically connected to a peripheral circuit region PER through a through contact.

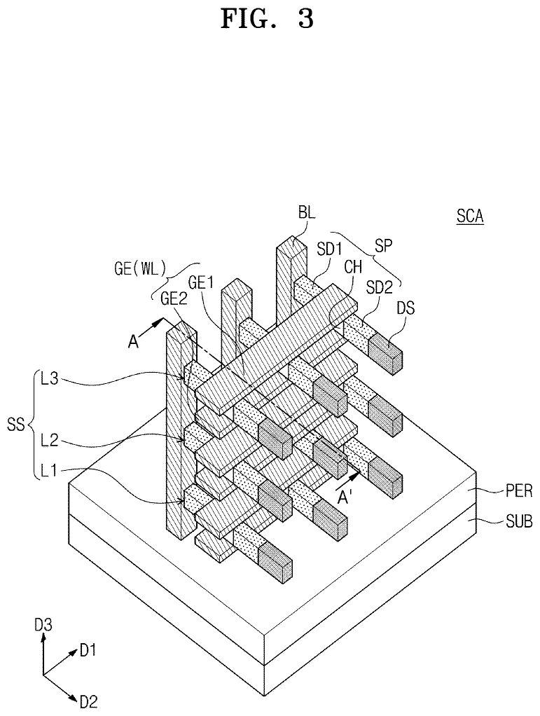

Hereinafter, in describing the embodiments illustrated in FIGS. 3 to 6, detailed descriptions about technical features that overlap with those described above with reference to FIGS. 1 and 2 are omitted and the differences are explained in detail.

Referring to FIGS. 1 and 3, the gate electrode GE may include a first gate electrode GE1 on the upper surface of the semiconductor pattern SP and a second gate electrode GE2 on a lower surface of the semiconductor pattern SP. In other words, the memory cell transistor according to an embodiment may be a double gate transistor in which the gate electrode GE is provided on both (e.g., opposing) sides of the channel region CH.

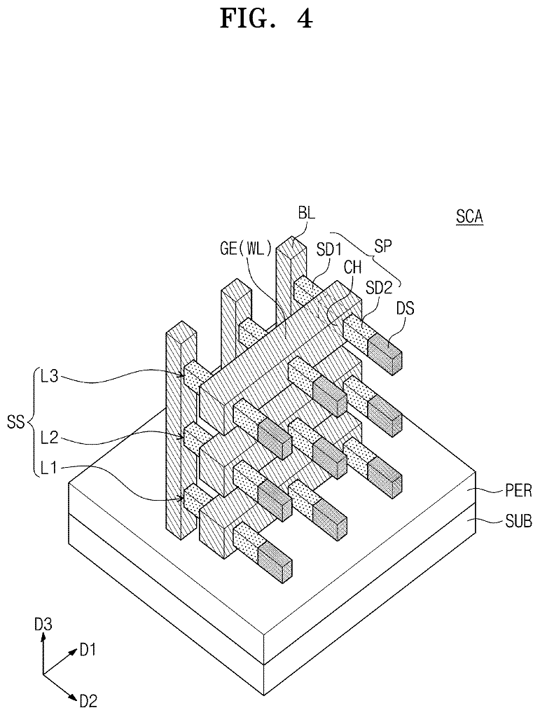

Referring to FIGS. 1 and 4, the gate electrode GE may surround the channel region CH of the semiconductor pattern SP. The term “surround” (or “cover” or “fill”) as may be used herein may not require completely surrounding (or covering or filling) the described elements or layers, but may, for example, refer to partially surrounding (or covering or filling) the described elements or layers, for example, with discontinuities or other spaces throughout. The gate electrode GE may be provided on an upper surface, a lower surface, and both (e.g., opposing) sidewalls of the channel region CH. In other words, the memory cell transistor according to an embodiment may be a gate-all-around transistor in which the gate electrode GE surrounds the channel region CH.

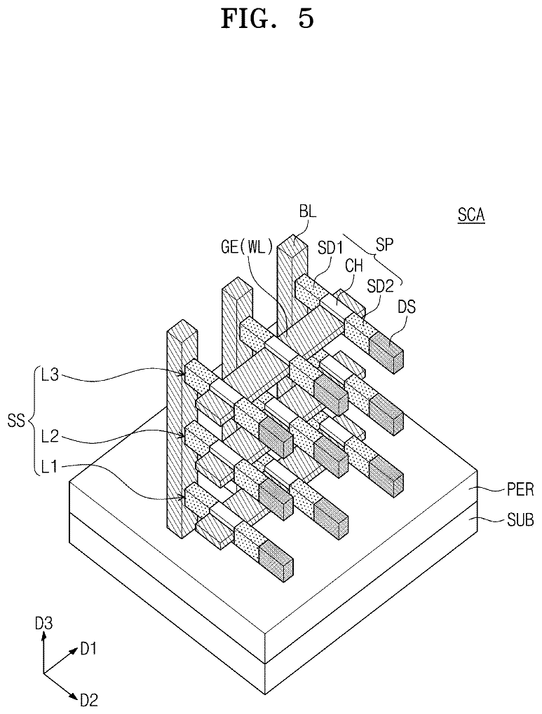

Referring to FIGS. 1 and 5, the gate electrode GE may extend in the first horizontal direction D1 while penetrating the channel region CH of the semiconductor pattern SP. The channel region CH may surround the gate electrode GE. In other words, the memory cell transistor according to an embodiment may be a channel-all-around transistor in which the channel region CH surrounds the gate electrode GE.

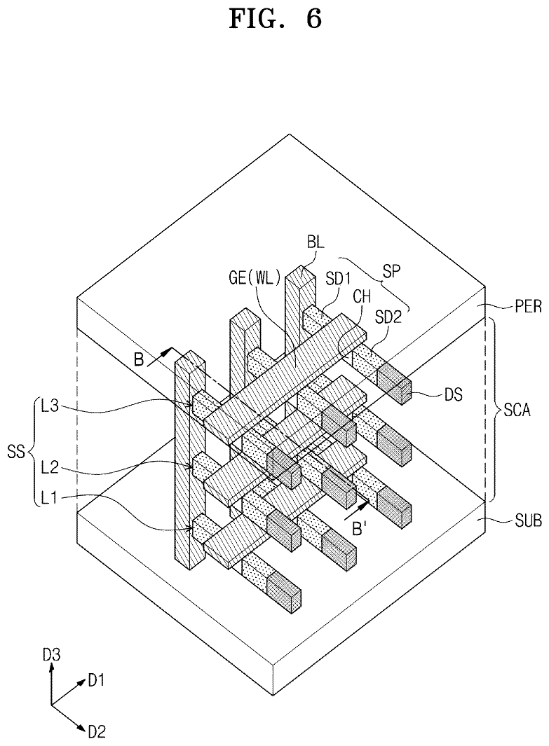

Referring to FIGS. 1 and 6, the sub-cell array SCA may be provided on the substrate SUB. The peripheral circuit region PER may be provided on the sub-cell array SCA, such that the sub-cell array SCA may be between the peripheral circuit region PER and the substrate SUB. As described above, the peripheral circuit region PER may include a circuit for operating the sub-cell array SCA.

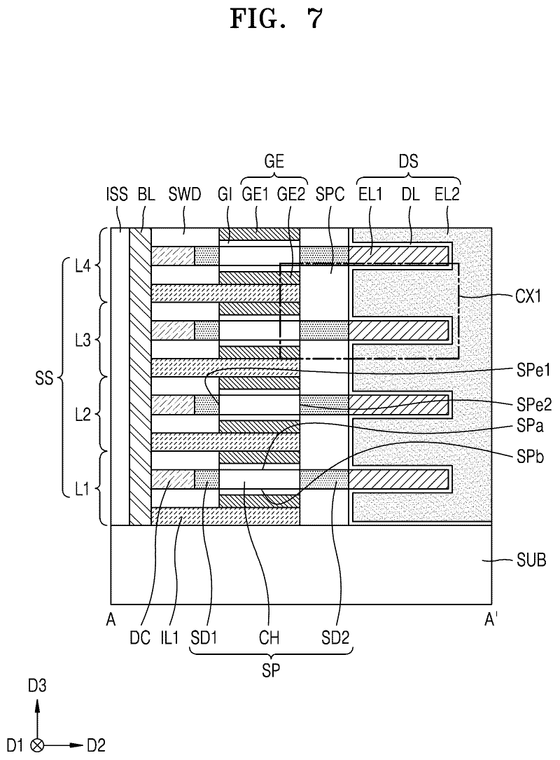

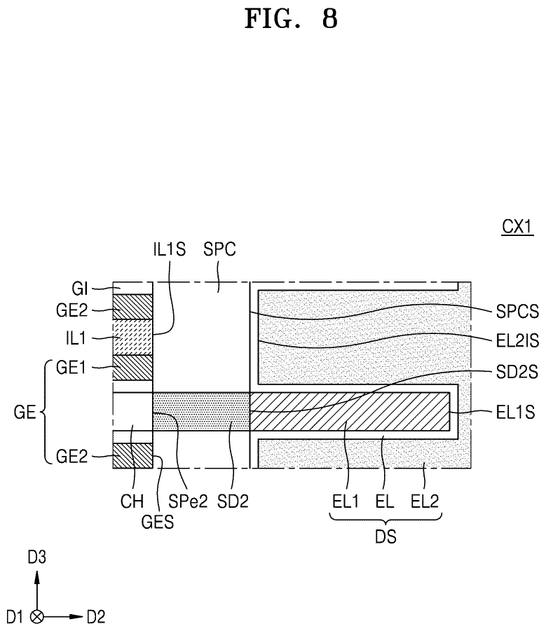

FIG. 7 is a cross-sectional view taken along line A-A′ of FIG. 3. FIG. 8 is an enlarged view of CX1 of FIG. 7. FIG. 8 is an enlarged view of CX1 of FIG. 7.

Referring to FIGS. 3 and 7, the stack structure SS may be provided on the substrate SUB. For example, the stack structure SS may have a form extending in the first horizontal direction D1 together with the gate electrode GE. Although not shown, the stack structure SS may be provided in multiple numbers, and the multiple stack structures SS may be arranged in the second horizontal direction D2.

The stack structure SS may include first to fourth layers L1 to L4 sequentially stacked on the substrate SUB. Each of the first to fourth layers L1 to L4 may include a first insulating film IL1, a semiconductor pattern SP, a gate electrode GE, a sidewall insulating pattern SWD, and a spacer SPC. Each of the first to fourth layers L1 to L4 may further include a direct contact DC (also referred to as a bit line contact DC) and a data storage element DS electrically connected to the semiconductor pattern SP. The first to fourth layers L1 to L4 according to embodiments are examples, and additional layers may be repeatedly stacked on the fourth layer L4.

The semiconductor pattern SP, the gate electrode GE, and the sidewall insulating pattern SWD may be provided on the first insulating film IL1. The first insulating film IL1 may vertically separate the gate electrode GE of an upper layer and the gate electrode GE of a lower layer from each other in the direction D3.

The gate electrode GE may include at least one of a doped semiconductor material, a conductive metal nitride, a metal, and a metal-semiconductor compound.

The semiconductor pattern SP may include a semiconductor material such as silicon, germanium, or silicon-germanium. The first insulating film IL1 may include at least one of a silicon oxide film, a silicon nitride film, a silicon oxynitride film, a carbon-including silicon oxide film, a carbon-including silicon nitride film, and a carbon-including silicon oxynitride film.

The semiconductor pattern SP may include the channel region CH, the first impurity region SD1, and the second impurity region SD2.

The channel region CH may have a first end SPe1 and a second end SPe2 facing the first end SPe1 in the second horizontal direction D2. The first impurity region SD1 may be arranged on the first end SPe1, and the second impurity region SD2 may be arranged on the second stage SPe2. The first end SPe1 may correspond to the first end described with reference to FIG. 2. The second end SPe2 may correspond to the second end described with reference to FIG. 2.

Specifically, the first impurity region SD1 may be arranged between the channel region CH and the bit line BL. Specifically, the second impurity region SD2 may be arranged between the channel region CH and the information storage element DS. The channel region CH may be disposed between the first impurity region SD1 and the second impurity region SD2.

For example, the channel region CH, the first impurity region SD1, and the second impurity region SD2 may be configured as one body i.e., a unitary member. In other words, no boundary or interface may be observed between the channel region CH and the first impurity region SD1, or between the channel region CH and the second impurity region SD2.

The first impurity region SD1 and the second impurity region SD2 may be regions in which the semiconductor pattern SP is doped with impurities. Accordingly, the first impurity region SD1 and the second impurity region SD2 may be of an n-type or p-type conductivity.

The impurity doping concentration of the second impurity region SD2 may increase away (i.e., with distance) from the gate electrode GE in the second horizontal direction D2. Conversely, the impurity doping concentration of the second impurity region SD2 may decrease in the opposite direction of the second horizontal direction D2 toward the gate electrode GE. This may be due to the fact that the method of forming the second impurity region SD2 uses the Gas Phase Doping (GPD) process.

For example, the impurity doping concentration of the second impurity region SD2 according to a distance from the gate electrode GE in the second horizontal direction D2 may increase uniformly or exponentially. However, the concept of the present embodiment is not limited thereto, and the impurity doping concentration of the second impurity region SD2 according to the distance from the gate electrode GE in the second horizontal direction D2 may increase irregularly.

The gate electrode GE of each of the first to fourth layers L1 to L4 may include a first gate electrode GE1 on a first surface SPa of the semiconductor pattern SP and a second gate electrode GE2 on a second surface SPb of the semiconductor pattern SP. The second surface SPb may face the first surface SPa in the vertical direction D3. For example, the first surface SPa may be an upper surface of the semiconductor pattern SP, and the second surface SPb may be a lower surface of the semiconductor pattern SP.

The first gate electrode GE1 and the second gate electrode GE2 may be vertically spaced apart from each other with the semiconductor pattern SP therebetween. In other words, the semiconductor pattern SP may be sandwiched between the first gate electrode GE1 and the second gate electrode GE2 provided above and below thereof, respectively.

The first gate electrode GE1 and the second gate electrode GE2 may extend in the first horizontal direction D1 parallel to each other. For example, the gate electrode GE of each of the first to fourth layers L1 to L4 may configure one word line WL (refer to FIG. 1). The gate electrode GE according to an embodiment may continuously cross the semiconductor patterns SP arranged in the first horizontal direction D1 within one layer.

A gate insulating pattern GI may be disposed between the first gate electrode GE1 and the second gate electrode GE2 and the semiconductor pattern SP. The gate insulating pattern GI may include a single film selected from a high-k dielectric film, a silicon oxide film, a silicon nitride film, and a silicon oxynitride film, or any combination thereof.

A transistor of the memory cell according to an embodiment may have a double gate structure in which the first gate electrode GE1 and the second gate electrode GE2 respectively are positioned above and below the body of the transistor (i.e., the semiconductor pattern SP). In other words, the transistor of the memory cell according to an embodiment may be a double-gate transistor as described above with reference to FIG. 3. The transistor of the memory cell according to an embodiment may have a double-gate structure, and thus, the channel controllability of the gate electrode GE may be improved.

The semiconductor patterns SP of each of the first to fourth layers L1 to L4 may be arranged in the first horizontal direction D1 separated from each other by vertical insulators (not shown).

Bit lines BL penetrating the stack structure SS may be provided. The bit lines BL may be separated from each other by vertical insulators (not shown). The bit lines BL may be arranged in the first horizontal direction D1. The bit line BL may correspond to the bit line BL described with reference to FIG. 1.

The bit line BL may be arranged on the first end SPe1 of the channel region CH. The direct contact DC may be arranged on the first end SPe1 of the channel region CH. The direct contact DC may be arranged between the bit line BL and the first impurity region SD1.

The bit line BL may be directly connected to the direct contact DC. The bit line BL may be electrically connected to the first impurity region SD1 through the direct contact DC.

The direct contact DC may include a metal silicide (e.g., cobalt silicide).

An insulating structure ISS covering sidewalls of the bit lines BL may be provided. The insulating structure ISS may extend in the first horizontal direction D1. The insulating structure ISS may include at least one of a silicon oxide film, a silicon nitride film, and a silicon oxynitride film.

The sidewall insulating pattern SWD may be arranged between the bit line BL and the gate electrode GE. The sidewall insulating pattern SWD may electrically insulate the bit line BL and the gate electrode GE.

The sidewall insulating pattern SWD may be arranged on an upper surface and a lower surface of the first impurity region SD1. The sidewall insulating pattern SWD may be arranged on an upper surface and a lower surface of the direct contact DC. The sidewall insulating pattern SWD may be arranged on an upper surface and a lower surface of the first insulating film IL1.

The information storage element DS may be arranged on the second end SPe2 of the channel region CH. The information storage element DS may be electrically connected to the second impurity region SD2.

The information storage element DS may be provided in multiple numbers. Each of the information storage elements DS may include a first electrode EL1, a dielectric film DL, and a second electrode EL2. The information storage elements DS may share one dielectric film DL and one second electrode EL2. In other words, a plurality of first electrodes EL1 may be provided in the stack structure SS, and one (e.g., a continuous) dielectric film DL may cover surfaces of the first electrodes EL1. The second electrode EL2 may be provided on the dielectric film DL.

Each of the first electrodes EL1 may have a cylinder shape, the interior of which is filled. The second electrode EL2 may be provided on an outer surface of the cylinder of the first electrode EL1.

The first electrodes EL1 may be respectively connected to the semiconductor patterns SP within one layer. Specifically, the first electrodes EL1 may respectively be connected to the second impurity regions SD2 within one layer. The first electrodes EL1 within one layer may be arranged in the first horizontal direction D1.

For example, the first electrode EL1 may include a metal silicide (e.g., cobalt silicide).

The second electrode EL2 may include at least one of a metal material (e.g., titanium, tantalum, tungsten, copper, or aluminum), a conductive metal nitride (e.g., titanium nitride or tantalum nitride), and a doped semiconductor material (e.g., doped silicon or doped germanium).

The dielectric film DL may include a high-k material (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or any combination thereof).

A spacer SPC may be disposed between the second electrode EL2 and the gate electrode GE. The spacer SPC may be disposed between the second impurity region SD2 of an upper layer and the second impurity region SD2 of a lower layer. The spacer SPC may separate the second impurity region SD2 of the upper layer and the second impurity region SD2 of the lower layer from each other in the vertical direction D3.

Referring to FIGS. 7 and 8 together, an outer sidewall SPCS of the spacer SPC may be spaced apart from an outer sidewall ELIS of the first electrode EL1. The outer side wall SPCS of the spacer SPC may be a sidewall that is spaced further away from the bit line BL among opposing sidewalls of the spacer SPC in the second horizontal direction D2. Similarly, the outer sidewall ELIS of the first electrode EL1 may be a sidewall that is spaced further away from the bit line BL among opposing sidewalls of the first electrode EL1 in the second horizontal direction D2.

The outer sidewall ELIS of the first electrode EL1 may be spaced further away from the gate electrode GE in the second horizontal direction D2 than the outer sidewall SPCS of the spacer SPC. Alternatively, the outer sidewall ELIS of the first electrode EL1 may be spaced further from the bit line BL in the second horizontal direction D2 than the outer sidewall SPCS of the spacer SPC. In other words, the outer sidewall SPCS of the spacer SPC may be closer to the gate electrode GE in the second horizontal direction D2 than the outer sidewall ELIS of the first electrode EL1. Alternatively, the outer sidewall SPCS of the spacer SPC may be closer to the bit line BL in the second horizontal direction D2 than the outer sidewall ELIS of the first electrode EL1.

The outer sidewall SPCS of the spacer SPC may be spaced apart from an outer sidewall ILIS of the first insulating film IL1. The outer sidewall ILIS of the first insulating film IL1 may be a sidewall that is spaced further from the bit line BL among opposing sidewalls of the first insulating film IL1 in the second horizontal direction D2.

The outer sidewall SPCS of the spacer SPC may be spaced further from the bit line BL in the second horizontal direction D2 than the outer sidewall ILIS of the first insulating film IL1. Alternatively, the outer sidewall SPCS of the spacer SPC may be spaced further from the gate electrode GE in the second horizontal direction D2 than the outer sidewall ILIS of the first insulating film IL1. In other words, the outer sidewall ILIS of the first insulating film IL1 may be closer to the bit line BL in the second horizontal direction D2 than the outer sidewall SPCS of the spacer SPC.

The outer sidewall SPCS of the spacer SPC may be aligned (e.g., in a line or co-linear) with an outer sidewall SD2S of the second impurity region SD2. Additionally or alternatively, the outer sidewall SPCS of the spacer SPC may be coplanar with the outer sidewall SD2S of the second impurity region SD2. The outer sidewall SD2S of the second impurity region SD2 may be a sidewall that is spaced further from the bit line BL among opposing sidewalls of the second impurity region SD2 in the second horizontal direction D2.

The outer sidewall SPCS of the spacer SPC may be spaced apart from an outer sidewall GES of the gate electrode GE. The outer sidewall GES of the gate electrode GE may be a sidewall that is spaced further from the bit line BL among the opposing sidewalls of the gate electrode GE in the second horizontal direction D2. The outer sidewall SPCS of the spacer SPC may be spaced further from the bit line BL in the second horizontal direction D2 than the outer sidewall GES of the gate electrode GE. In other words, the outer sidewall GES of the gate electrode GE may be closer to the bit line BL in the second horizontal direction D2 than the outer sidewall SPCS of the spacer SPC, which is opposite the gate electrode GE.

The spacer SPC may be spaced apart from the second electrode EL2 in the second horizontal direction D2 with a dielectric film DL therebetween. The outer sidewall SPCS of the spacer SPC may be spaced apart from an inner sidewall EL2IS of the second electrode EL2 with the dielectric film DL therebetween. The inner sidewall EL2IS of the second electrode EL2 may be a sidewall that is the closest to the gate electrode GE in the second horizontal direction D2 among the sidewalls of the second electrode EL2 in the second horizontal direction D2.

The inner sidewall EL2IS of the second electrode EL2 may be closer to the gate electrode GE in the second horizontal direction D2 than the outer sidewall ELIS of the first electrode EL1, which is opposite the second impurity region SD2.

For example, the outer sidewall ILIS of the first insulating film IL1 may be aligned in a line or co-linear with the outer sidewall GES of the gate electrode GE. Additionally or alternatively, the outer sidewall ILIS of the first insulating film IL1 may be coplanar with the outer sidewall GES of the gate electrode GE.

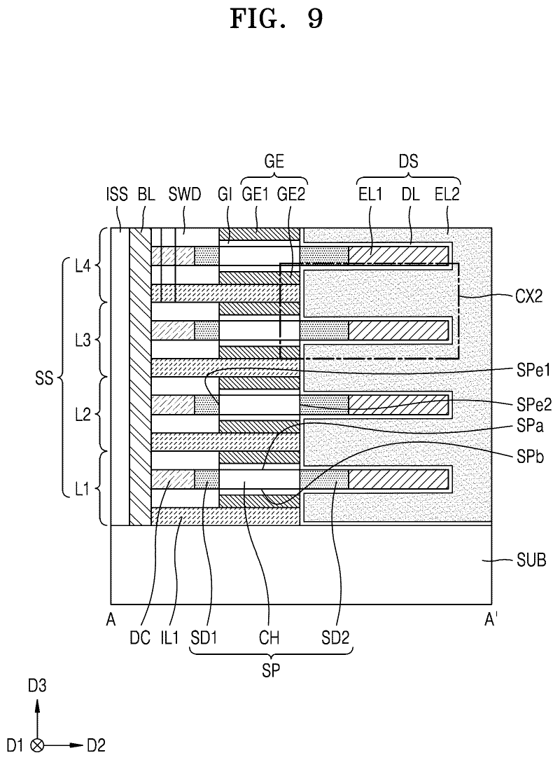

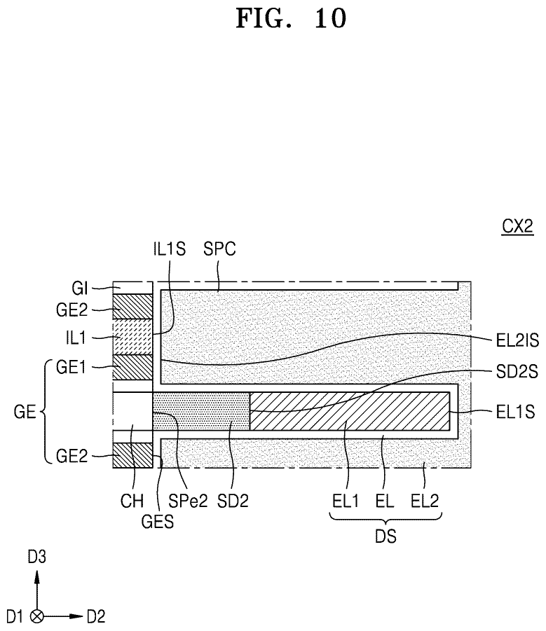

FIG. 9 is a cross-sectional view taken along line A-A′ of FIG. 3. FIG. 10 is an enlarged view of CX2 of FIG. 9. Hereinafter, descriptions that overlap with those described with reference to FIG. 3, FIG. 7, and FIG. 8 will be omitted, and differences will be primarily described.

Referring to FIG. 3, FIG. 9, and FIG. 10, the spacer SPC may be omitted from the three-dimensional semiconductor memory device. Therefore, the inner sidewall EL2IS of the second electrode EL2 may protrude further from (or towards) the gate electrode GE in the second horizontal direction D2.

The inner sidewall EL2IS of the second electrode EL2 may be closer to the gate electrode GE in the second horizontal direction D2 than the outer sidewall SD2S of the second impurity region SD2. In other words, the outer sidewall SD2S of the second impurity region SD2 may be spaced further from the gate electrode GE in the second horizontal direction D2 than the inner sidewall EL2IS of the second electrode EL2.

The outer sidewall ILIS of the first insulating film IL1 may be closer to the gate electrode GE in the second horizontal direction D2 than the inner sidewall EL2IS of the second electrode EL2. In other words, the inner sidewall EL2IS of the second electrode EL2 may be spaced further from the gate electrode GE in the second horizontal direction D2 than the outer sidewall ILIS of the first insulating film IL1.

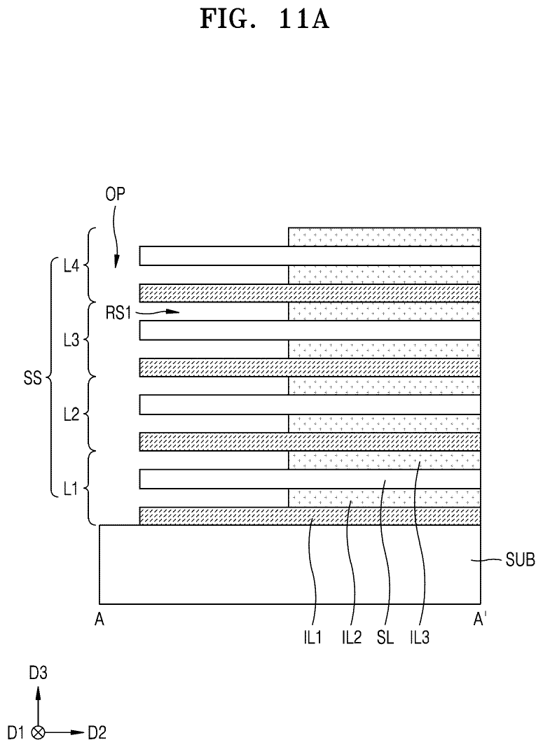

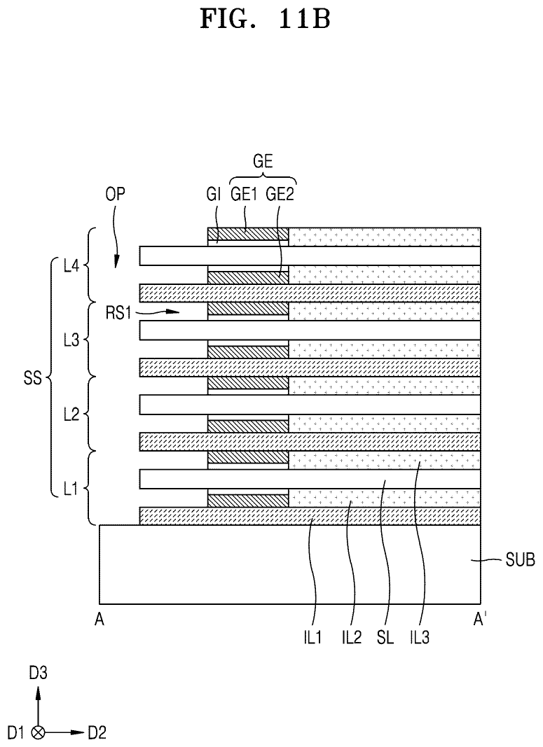

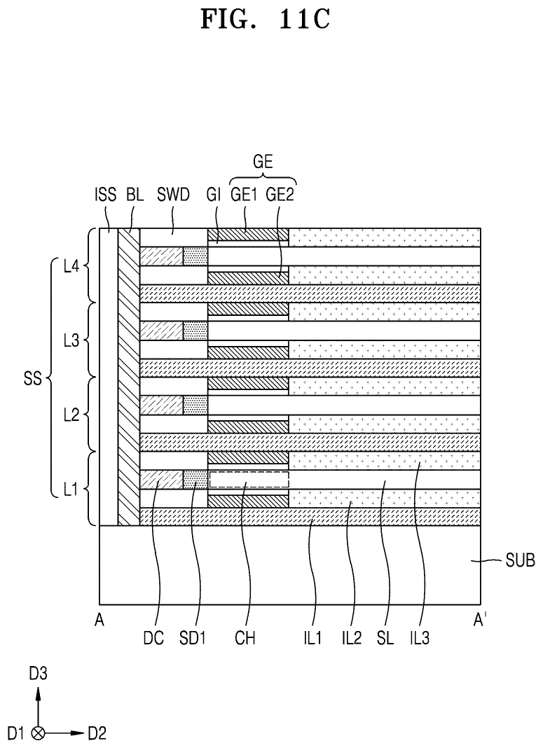

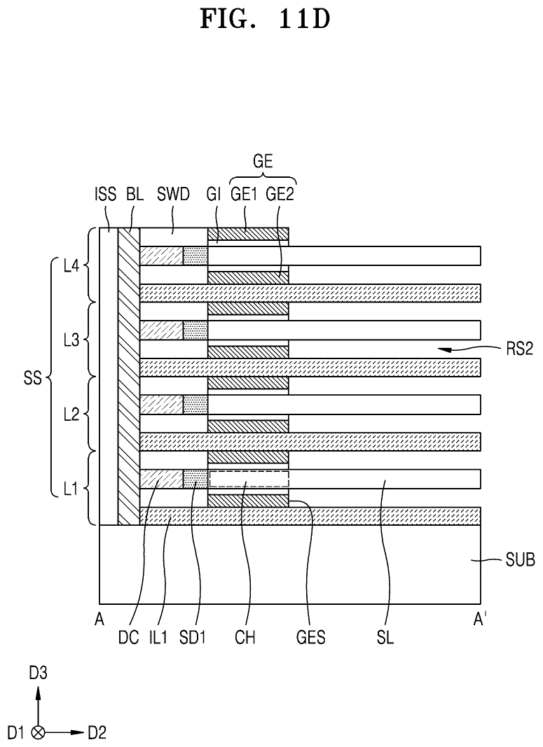

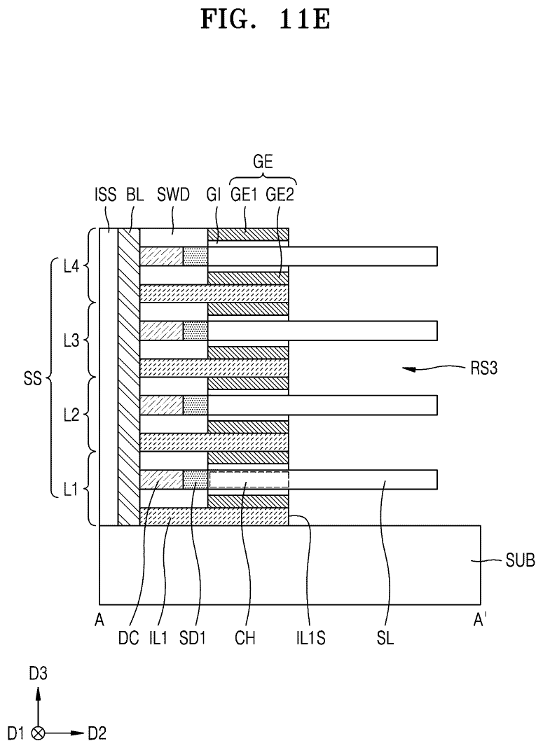

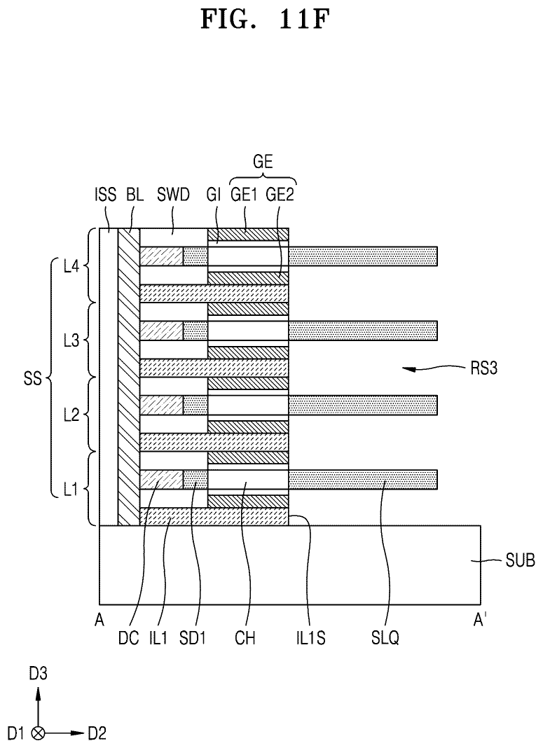

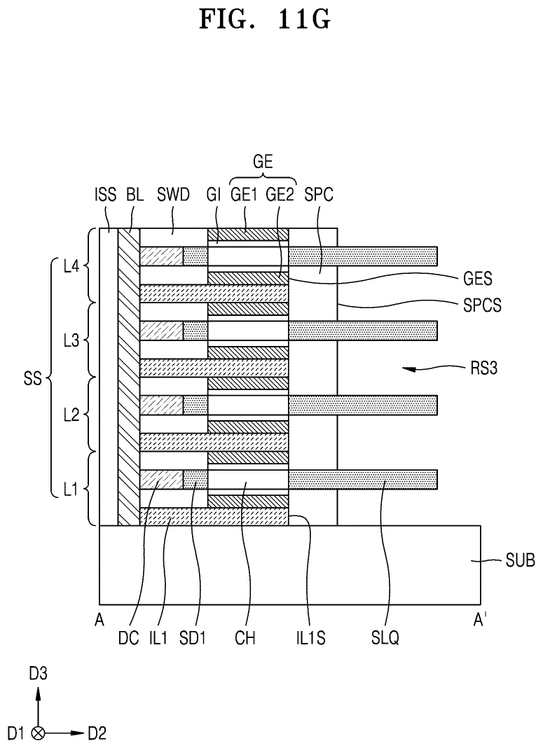

FIGS. 11A to 11G are diagrams showing a method of manufacturing a semiconductor memory device of FIG. 7, and are cross-sectional views taken along line A-A′ of FIG. 3.

Referring to FIG. 11A, a stack structure SS may be formed on a substrate SUB. The forming of the stack structure SS may include sequentially forming first to fourth layers L1 to L4.

Specifically, the forming of each of the first to fourth layers L1 to LA may include forming a first insulating film IL1, forming a second insulating film IL2 on the first insulating film IL1, forming a semiconductor film SL on the second insulating film IL2, and forming a third insulating film IL3 on the semiconductor film SL.

In other words, each of the first to fourth layers L1 to LA may include the first insulating film IL1, the second insulating film IL2, the semiconductor film SL, and the third insulating film IL3 that are sequentially laminated or stacked.

The first insulating film IL1, the second insulating film IL2, and the third insulating film IL3 may include at least one of a silicon oxide film, a silicon nitride film, a silicon oxynitride film, a carbon-including silicon oxide film, a carbon-including silicon nitride film, and a carbon-including silicon oxynitride film.

The second insulating film IL2 and the third insulating film IL3 may include the same material. The second insulating film IL2 and the third insulating film IL3 may include a material that has etch-selectivity with respect to the first insulating film IL1. For example, the first insulating film IL1 may include a silicon oxide film, and the second insulating film IL2 and the third insulating film IL3 may include a silicon nitride film.

The semiconductor film SL may include a semiconductor material such as silicon, germanium, or silicon-germanium.

An opening OP penetrating the stack structure SS may be formed. Although not shown, a plurality of openings OP may be provided. The opening OP may expose an upper surface of the substrate SUB.

The second insulating film IL2 and the third insulating film IL3 exposed by the opening OP may be partially etched. Specifically, a wet etching process may be performed to selectively etch the second insulating film IL2 and the third insulating film IL3 through the opening OP. During the wet etching process, the first insulating films IL1 and the semiconductor films SL may remain unchanged or substantially unaffected by the selective etch process.

During the wet etching process, the second insulating film IL2 and the third insulating film IL3 can be partially etched to form first recesses RS1. Each of the first recesses RS1 may be at the same vertical level (relative to the substrate SUB) as one of the second insulating films IL2 or one of the third insulating films IL3.

Sidewalls of the second insulating films IL2 and the third insulating films IL3 may be exposed by the first recesses RS1. A portion of an upper surface and a portion of a lower surface of the semiconductor film SL may be exposed by the first recesses RS1. A portion of an upper surface and a portion of a lower surface of the first insulating film IL1 may be exposed by the first recesses RS1.

Referring to FIG. 11B, a gate insulating pattern GI and a gate electrode GE may be formed within the first recesses RS1. The forming of the gate insulating pattern GI and the gate electrode GE within the first recesses RS1 may include forming a gate insulating film (not shown) that conformally covers an exposed upper surface, lower surface, and sidewall of the semiconductor film SL, forming a gate electrode film (not shown) covering a surface of the gate insulating film, and recessing the gate insulating film and the gate electrode film through the opening OP and the first recesses RS1.

The gate electrode GE may include a first gate electrode GE1 on the upper surface of the semiconductor film SL and a second gate electrode GE2 on the lower surface of the semiconductor film SL.

Referring to FIG. 11C, a first impurity region SD1 and a direct contact or bit line contact DC may be formed.

The forming of the first impurity region SD1 and the direct contact DC may include performing a gas phase doping (GPD) process through the opening OP and the first recesses RS1, forming a portion of a sidewall insulating pattern SWD, silicidating (or siliciding) a portion of the semiconductor film SL, and forming the remaining portion of the sidewall insulating pattern SWD. At this time, a portion of the semiconductor film SL that overlaps the gate electrode GE in the vertical direction D3 may be referred to as a channel region CH. Components or layers described with reference to “overlap” in a particular direction may be at least partially obstructed by one another when viewed along a line extending in the particular direction or in a plane perpendicular to the particular direction.

At this time, the GPD process may denote doping a semiconductor material with an impurity using a gas. The ion implantation, which is an existing doping method, has a disadvantage in damaging a lattice of the semiconductor material. In addition, another existing doping method, a thermal diffusion method, has a disadvantage in that the thermal diffusion method takes a long process time and is difficult to control a diffusion direction. On the other hand, if the GPD process is used, because a gas is used as a doping material, the lattice of the semiconductor material may not be damaged and the process time may be shortened. In addition, there is an advantage in that the degree of diffusion may be controlled by adjusting variables such as time during the GPD process.

The portion of the sidewall insulating pattern SWD may be arranged on an upper surface and a lower surface of the first impurity region SD1.

The first impurity region SD1 may be formed by doping a portion of the semiconductor film SL, and the direct contact or bit line contact DC may be formed by silicidating or siliciding a portion of the semiconductor film SL. Therefore, the first impurity region SD1 and the direct contact DC may be portions of the semiconductor film SL, but the present embodiment is not limited thereto.

Subsequently, a bit line BL and an insulating structure ISS covering a sidewall of the bit line BL may be formed.

Referring to FIG. 11D, the remaining second insulating film IL2 and the third insulating film IL3 may be removed. The removal of the second insulating film IL2 and the third insulating film IL3 may be performed through a wet etching process utilizing etch selectivity with respect to the first insulating film IL1.

Second recesses RS2 may be formed in the space where the second insulating film IL2 and the third insulating film IL3 are removed through the wet etching process. A portion of the semiconductor film SL may be exposed by the second recesses RS2.

Referring to FIG. 11E, a portion of the first insulating film IL1 exposed through the second recesses RS2 may be removed. At this time, a portion of the semiconductor film SL may also be removed. Third recesses RS3 may be formed when a portion of the first insulating film IL1 is removed. The third recess RS3 may be a space that is a combination of the second recess RS3 and a space where the portion of the removed first insulating film IL1 is located

Due to the third recess RS3, a distance between the semiconductor film SL of an upper layer and the semiconductor film SL of a lower layer in the vertical direction D3 may increase. In addition, due to the third recess RS3, the semiconductor film SL may have a form in which the semiconductor film SL protrudes in the second horizontal direction D2 from an outer sidewall ILIS of the first insulating film IL1. That is, due to the third recess RS3, it is easy for a substance in the gas phase to reach the exposed surface of the semiconductor film SL.

As a portion of the first insulating film IL1 is removed, the outer sidewall ILIS of the first insulating film IL1 may be aligned with the outer sidewall GES of the gate electrode GE.

Referring to FIG. 11F, a GPD process may be performed through the third recesses RS3. Due to the GPD process, an impurity may be doped on other exposed portions of the semiconductor film SL. As a result, a doped semiconductor film SLQ may be formed from the semiconductor film SL. A second impurity region SD2 and a first electrode EL1, which will be described later, may be formed from the doped semiconductor film SLQ.

The doped semiconductor film SLQ may be a product formed by performing a GPD process through the third recess RS3. Therefore, the impurity doping concentration of the doped semiconductor film SLQ may increase away from (i.e., with distance from) the gate electrode GE in the second horizontal direction D2.

Referring to FIG. 11G, a spacer SPC may be formed between the doped semiconductor film SLQ of an upper layer and the doped semiconductor film SLQ of a lower layer. A thickness of the spacer SPC in the second horizontal direction D2 may be freely or easily controlled. The thickness of the spacer SPC in the second horizontal direction D2 may be controlled so that an outer sidewall SPCS of the spacer SPC reaches (e.g., overlaps in the vertical direction D3) a portion of the doped semiconductor film SLQ having the most appropriate or desired impurity doping concentration to be used as a source/drain.

Referring again to FIG. 7, a portion of the doped semiconductor film SLQ may be silicidated or silicided to form the first electrode EL1. Another portion of the doped semiconductor film SLQ that is not the first electrode EL1 (i.e., a portion of the doped semiconductor film SLQ that is not silicided) may become or form the second impurity region SD2.

Subsequently, a dielectric film DL that conformally covers the exposed surface of the first electrode EL1 may be formed. Also, a second electrode EL2 may be formed. As a result, a three-dimensional semiconductor memory device may be formed.

According to an embodiment, the third recess RS3 may be formed by removing a portion of the first insulating film IL1 through the second recesses RS2. Due to the third recess RS3, a distance between the semiconductor film SL of an upper layer and the semiconductor film SL of a lower layer in the vertical direction D3 may be increased. As a result, if the GPD process is performed, the impurity concentration doped into the semiconductor film SL (also referred to as an impurity doping concentration) may be increased, and thus, the doping concentration of the second impurity region SD2 to be formed later may be easily controlled.

When the GPD process is performed, the impurity concentration of the doped semiconductor film SLQ may decrease toward the gate electrode GE in the second horizontal direction D2. At this time, a thickness of the spacer SPC in the second horizontal direction D2 may be freely controlled. By freely adjusting the thickness of the spacer SPC, the position of the second impurity region SD2 adjacent to the first electrode EL1 in the second horizontal direction D2 may be freely adjusted (e.g., by exposing a portion of the doped semiconductor film SLQ for silicidation to form the first electrode EL1). That is, the impurity doping concentration of the second impurity region SD2 may be adjusted according to the user's intention. As a result, because the contact resistance between the second impurity region SD2 and the first electrode EL1 may be reduced, the electrical characteristics and reliability of the three-dimensional semiconductor memory device may be improved.

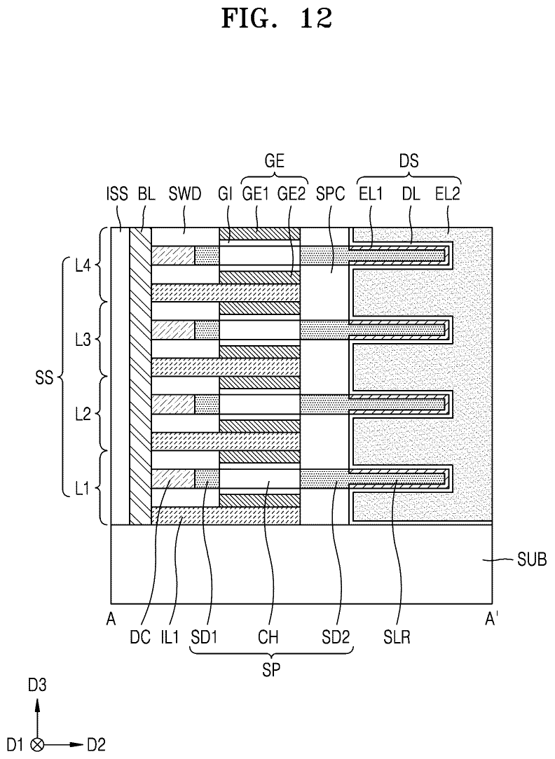

FIG. 12 is a cross-sectional view taken along the line A-A′ of FIG. 3. Hereinafter, descriptions that overlap with those described with reference to FIG. 3 and FIG. 7 will be omitted, and differences will be primarily described.

Referring to FIG. 12, the first electrode EL1 may have a hollow cylinder shape. Alternatively, the first electrode EL1 may have a rectangular parallelepiped shape with an empty interior and no left sidewall, i.e., a cylinder shape that is open on an end facing or adjacent the gate electrode GE. The portion of the first electrode EL1 of FIG. 7, excluding or other than the first electrode EL1 of FIG. 12, may be a doped semiconductor film SLR. The doped semiconductor film SLR may be a part of the doped semiconductor film SLQ of FIG. 11G.

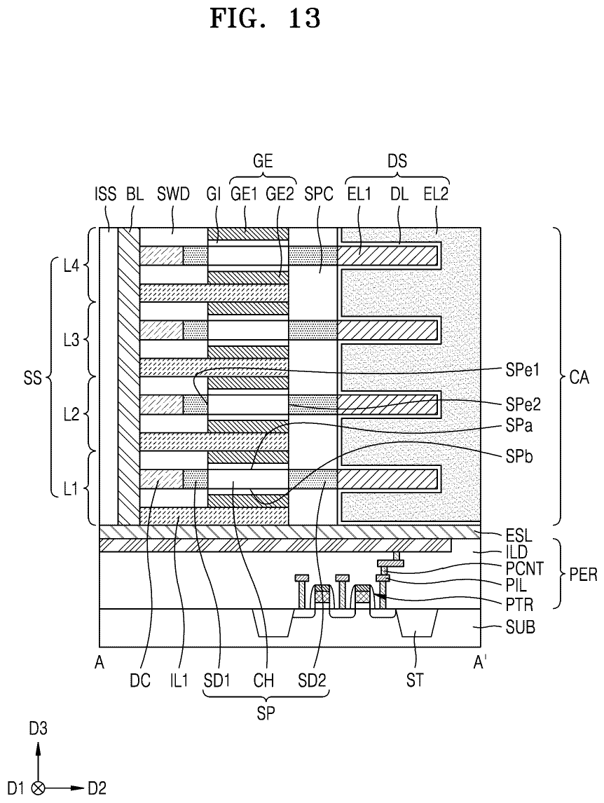

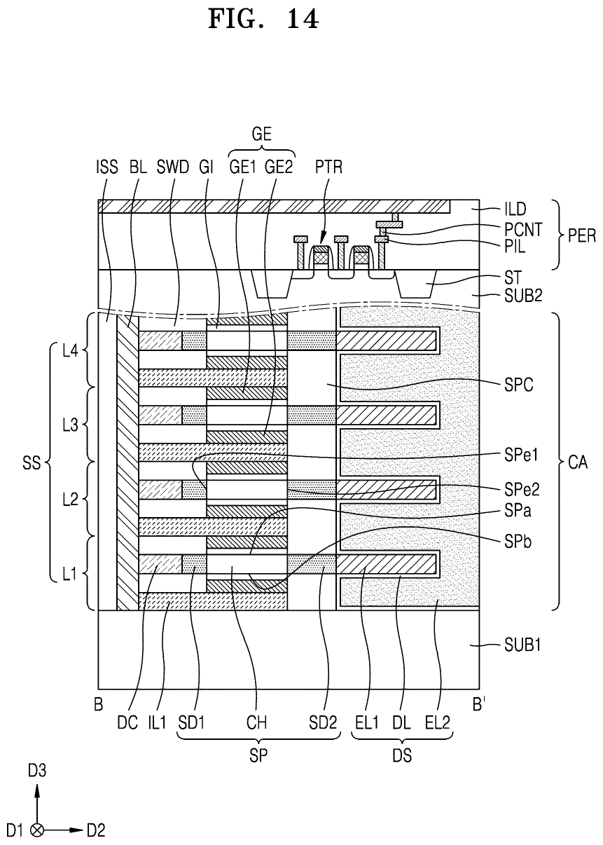

FIG. 13 is a cross-sectional view taken along line A-A′ of FIG. 3. FIG. 14 is a cross-sectional view taken along line B-B′ of FIG. 6. Hereinafter, descriptions that overlap with those described with reference to FIG. 3 and FIG. 7 will be omitted, and differences will be primarily described.

First, referring to FIG. 7 and FIG. 13, a cell array CA described with reference to FIG. 1 may be provided on a substrate SUB. The cell array CA may include a stack structure SS. A peripheral circuit region PER may be provided between the cell array CA and the substrate SUB. The peripheral circuit region PER may include a circuit for operating the cell array CA.

Specifically, the peripheral circuit region PER may include peripheral transistors PTR, peripheral wirings PIL on the peripheral transistors PTR, and peripheral contacts PCNT vertically connecting the peripheral wirings PIL. Although not shown, the peripheral wirings PIL may be electrically connected to the cell array CA through a through contact. An etch stop layer ESL may be additionally disposed between the cell array CA and the peripheral circuit region PER.

The semiconductor memory device according to an embodiment may have a cell-on-periphery (COP) structure in which memory cells are provided on the peripheral circuit region PER as described above with reference to FIGS. 1 and 2. By three-dimensionally stacking the peripheral circuit region PER and the cell array CA, an area of the semiconductor memory chip may be reduced, and high integration of the circuit may be implemented.

Referring to FIG. 14, the cell array CA may be provided on a first substrate SUB1. A second substrate SUB2 may be provided on the cell array CA. A peripheral circuit region PER may be provided on the second substrate SUB2. The peripheral circuit region PER may include a circuit for operating the cell array CA.

The forming of a semiconductor memory device according to an embodiment may include forming the cell array CA on a first substrate SUB1, forming the peripheral circuit region PER on a second substrate SUB2, and attaching the second substrate SUB2 on the cell array CA by using a wafer bonding method.

The semiconductor memory device according to an embodiment may have a Peri On Cell (POC) structure in which a peripheral circuit region is provided on a memory cell as described above with reference to FIG. 1 and FIG. 6. By three-dimensionally stacking the cell array CA and the peripheral circuit region PER, an area of the semiconductor memory chip may be reduced, and high circuit integration may be implemented.

While the inventive concept has been particularly shown and described with reference to embodiments thereof, it will be understood that various changes in form and details may be made therein without departing from the scope of the following claims.

What is claimed is:

1. A semiconductor memory device comprising:
a stack structure comprising a plurality of layers stacked on a substrate, each of the plurality of layers comprising a semiconductor pattern, a gate electrode extending in a first direction on the semiconductor pattern, and an information storage element electrically connected to the semiconductor pattern;
a bit line on one side of the stack structure and extending in a direction perpendicular to the substrate; and
a spacer adjacent to the gate electrode in a second direction intersecting the first direction,
wherein the semiconductor pattern comprises a first impurity region adjacent to the bit line, a second impurity region adjacent to the information storage element, and a channel region between the first impurity region and the second impurity region,
wherein the information storage element comprises a first electrode electrically connected to the second impurity region, and
wherein an outer sidewall of the spacer, which is opposite the gate electrode, is closer to the gate electrode than an outer sidewall of the first electrode, which is opposite the second impurity region.

2. The semiconductor memory device of claim 1, wherein an outer sidewall of the second impurity region that is opposite the channel region and the outer sidewall of the spacer are aligned in the direction perpendicular to the substrate.

3. The semiconductor memory device of claim 1, wherein
each of the plurality of layers further comprises an insulating film under the gate electrode, and
an outer sidewall of the insulating film, which is opposite the bit line, is closer to the bit line in the second direction than the outer sidewall of the spacer.

4. The semiconductor memory device of claim 3, wherein the outer sidewall of the insulating film is aligned with an outer sidewall of the gate electrode in the direction perpendicular to the substrate.

5. The semiconductor memory device of claim 1, wherein
the information storage element further comprises a second electrode and a dielectric film between the first electrode and the second electrode, and
an inner sidewall of the second electrode is spaced further from the gate electrode in the second direction than an outer sidewall of the second impurity region.

6. The semiconductor memory device of claim 1, wherein the spacer overlaps the second impurity region in the direction perpendicular to the substrate.

7. The semiconductor memory device of claim 1, wherein the gate electrode comprises a first gate electrode on an upper surface of the channel region and a second gate electrode on a lower surface of the channel region.

8. The semiconductor memory device of claim 1, wherein the gate electrode is on an upper surface, a lower surface, and opposing sidewalls of the channel region.

9. The semiconductor memory device of claim 1, wherein
each of the plurality of layers further comprises an insulating film under the gate electrode, and
an outer sidewall of the insulating film, which is opposite the bit line, is closer to the bit line in the second direction than the outer sidewall of the first electrode.

10. The semiconductor memory device of claim 1, wherein the first electrode includes a metal silicide.

11. The semiconductor memory device of claim 1, wherein the first electrode has a rectangular shape with a hollow interior and an opening on one end.

12. A semiconductor memory device comprising:
a stack structure comprising a plurality of layers stacked on a substrate, each of the plurality of layers comprising a semiconductor pattern, a gate electrode extending in a first direction on the semiconductor pattern, and an information storage element electrically connected to the semiconductor pattern;
a bit line on one side of the stack structure and extending in a direction perpendicular to the substrate; and
a spacer adjacent to the gate electrode in a second direction intersecting the first direction,
wherein the semiconductor pattern comprises a first impurity region adjacent to the bit line, a second impurity region adjacent to the information storage element, and a channel region between the first impurity region and the second impurity region, and
wherein an impurity concentration of the second impurity region increases away from the bit line in the second direction.

13. The semiconductor memory device of claim 12, wherein an impurity concentration in the first impurity region increases towards the bit line in the second direction.

14. The semiconductor memory device of claim 12, further comprising:
a peripheral circuit region between the substrate and the stack structure,
wherein the peripheral circuit region comprises peripheral transistors, peripheral wirings on the peripheral transistors, and peripheral contacts extending in the direction perpendicular to the substrate and connecting the peripheral wirings.

15. The semiconductor memory device of claim 12, wherein the gate electrode and the spacer are in direct contact.

16. The semiconductor memory device of claim 12, wherein
the plurality of layers comprises a first layer and a second layer which are adjacent to each other in the direction perpendicular to the substrate, and
the spacer contacts the second impurity region of the first layer and the second impurity region of the second layer.

17. The semiconductor memory device of claim 12, further comprising:
a bit line contact directly connecting the bit line and the first impurity region, and
the bit line contact includes a metal silicide.

18. The semiconductor memory device of claim 17, further comprising:
a sidewall insulating pattern on at least a portion of an upper surface and at least a portion of a lower surface of the bit line contact.

19. A semiconductor memory device comprising:
a substrate;
an insulating film on the substrate;
a semiconductor pattern on the insulating film, the semiconductor pattern comprising a channel region, a first impurity region on a first end of the channel region, and a second impurity region on a second end of the channel region, wherein the second end faces the first end in a first direction;
a gate electrode intersecting the semiconductor pattern in a second direction that intersects the first direction;
a gate insulating pattern between the channel region and the gate electrode;
a spacer adjacent to the gate electrode and the insulating film in the first direction, the spacer overlapping the second impurity region in a direction perpendicular to the substrate;
a bit line adjacent to the first impurity region in the first direction, the bit line being electrically connected to the first impurity region; and
an information storage element electrically connected to the second impurity region, the information storage element comprising a first electrode directly connected to the second impurity region, a second electrode, and a dielectric film therebetween,
wherein an outer sidewall of the first electrode, which is opposite the second impurity region, is farther from the gate electrode in the first direction than an outer sidewall of the spacer, which is opposite the gate electrode.

20. The semiconductor memory device of claim 19, wherein an impurity concentration of the second impurity region increases away from the bit line in the first direction.
